(19) United States
(12) Patent Application Publication
(10) Pub. No.: US 2013/0027053 A1
(43) Pub. Date: Jan. 31, 2013

(54) METHOD OF TESTING PARALLEL POWER CONNECTIONS OF SEMICONDUCTOR DEVICE

(71) Applicants: Lini LEE, Puchong (MY); Feng Liu, Tianjin (CN); Ruijie Peng, Tianjin (CN)

(72) Inventors: Lini LEE, Puchong (MY); Feng Liu, Tianjin (CN); Ruijie Peng, Tianjin (CN)

(73) Assignee: FREESCALE SEMICONDUCTOR, INC., Austin, TX (US)

(21) Appl. No.: 13/495,013

(22) Filed: Jun. 13, 2012

(30) Foreign Application Priority Data
Jul. 28, 2011 (CN) 201110361920.2

(51) Int. Cl. G01R 31/04; G01R 17/02

(52) U.S. Cl. 324/538; 324/98

(57) ABSTRACT

A semiconductor device has an internal power bus, parallel power connections for connecting the power bus with an external power supply and a test module. The test module includes a sensor for producing first and second differential sensor signals that are functions of voltages at spaced positions in one of the parallel connections produced by current in the parallel connection. The test module includes first and second balanced differential pair comparators that receive first and second reference signals and produce a first comparator signal that is a function of the relative values of the first differential sensor signal and the first reference signal, and a second comparator signal that is a function of the relative values of the second differential sensor signal and the second reference signal. The test module includes an output element that produces an output signal that is a function of the first and second comparator signals.

### BACKGROUND OF THE INVENTION

The present invention is directed to a method of testing parallel power connections of a semiconductor device and to a semiconductor device suitable for testing parallel power connections in the device.

Electrical power for an integrated circuit (‘IC’) device is supplied by applying a voltage to external contact surfaces of the IC device, such as pins or leads, connected to internal pads of the device. Typically, a single pair of power contact surfaces is insufficient to deliver the required current for an IC and causes problems such as electro-migration and voltage bounce effects in the internal power supply nets of the IC device produced by high transient peak currents in low voltage, high speed, simultaneously switching periphery buffers of the device, for example. To reduce such problems, IC devices often include sets of multiple power contact surfaces for both positive and negative (or ground) power supplies. Each set comprises a plurality of power contact surfaces which are connected through individual parallel internal connections to an internal power bus or rail of the IC device, and are connected through individual parallel external connections to the same external power supply, through an external power rail for example.

Quality considerations necessitate testing of the IC device, including its external power connections, after the manufacturing operations and assembly of the voltage supply are completed, at ‘final test’. Known test methods, for example based on measuring the voltage on the internal power bus, are insufficiently effective to detect a faulty connection of an individual one of the power contact surfaces between the internal power bus and the external voltage supply in the presence of parallel connections between the same internal power bus and the external voltage supply through other power contact surfaces of the same set. Thus, it would be advantageous to be able to test and detect faulty connections between the internal power bus and the external voltage supply.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a schematic circuit diagram of a set of connections between an internal power bus of a semiconductor device and an external voltage supply;

FIG. 2 is a schematic diagram of a known module of a semiconductor device for testing the individual connections of FIG. 1;

FIG. 3 is a schematic diagram of a test module in a semiconductor device for testing the individual connections of FIG. 1 in accordance with one embodiment of the invention;

FIG. 4 is a schematic diagram of an analog monitor of the test module of FIG. 3;

FIG. 5 is a simplified circuit diagram of inter-connected differential sensor and amplifier elements of the analog monitor of FIG. 4;

FIG. 6 is a simplified circuit diagram of a common mode feedback element of the analog monitor of FIG. 4;

FIG. 7 is a simplified circuit diagram of a differential comparator and latch element of the analog monitor of FIG. 4; and

FIGS. 8 and 9 are graphs of signals appearing in operation of the test module of FIG. 3.

### DETAILED DESCRIPTION OF PREFERRED EMBODIMENTS OF THE INVENTION

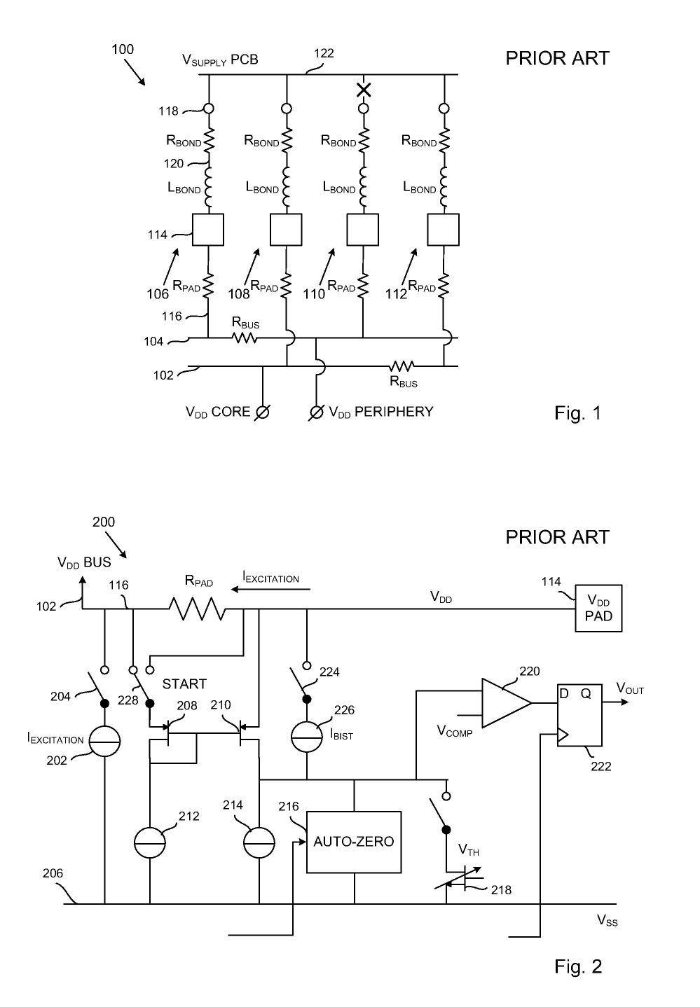

FIGS. 1 and 2 illustrate a conventional semiconductor device 100 comprising internal power buses V_{DD} CORE 102 and V_{DD} PERIPHERY 104 for the IC core and peripherals, parallel power connections 106, 108, 110 and 112 for connecting the internal power bus with an external power supply, and a test module 200. The power buses 102 and 104 are shown for the V_{DD} voltage connections but similar buses with parallel power connections (not shown) are also provided for connecting the internal V_{SS} opposite polarity power (or ground) bus with the external power supply and a test module similar to the test module 200 but adapted for the opposite polarity may be provided.

The parallel power connections 106, 108, 110 and 112 each comprise a pad such as 114 presenting a contact surface on the semiconductor chip and which is connected internally of the chip to the bus 102 or 104 by a connector such as 116 presenting a resistance R_{PAD}. Each pad 114 is connected to external leads or contact surfaces such as 118 of the package of the semiconductor device 100, by connectors such as 120, in the form of bonding wires for example, presenting resistances R_{BOND} and inductances L_{BOND}. The external leads or contact surfaces such as 118 of the package are connected in parallel to a power supply bus 122, on a printed circuit board (‘PCB’) by soldering for example. In FIG. 1, by way of example, the connection 110 is shown as faulty between the power supply bus 122 and the external lead or contact surface 118, having a high resistance or open circuit, such as could be produced by a bonding wire lifting. Such a faulty connection will not prevent the bonding pad 114 of the connection 110 from being maintained at the voltage V_{DD} of the bus 102 or 104 by current flowing in the other parallel connections, but the faulty connection 110 will not contribute its expected share of current to the supply of power.

A test module 200 is used to detect such a faulty connection by a test procedure applied selectively to each of the parallel connections 106 to 112 in sequence during inspection, after the manufacturing operations and assembly to the voltage supply are completed. In a known test module 200, illustrated in FIG. 2, the procedure involves a generator 202 generating an excitation current I_{EXCITATION} of the order of 100 mA by applying a test voltage between the internal power supply buses 102 and 206 during the test. On closure of a test switch 204, current flows through the connection between the bonding pad 114 and the internal power bus 102 (or 104) and then to the opposite polarity bus 206, the return path being completed through the PCB power supply rail 122 and all the parallel V_{DD} and V_{SS} power supply connections. The excitation current I_{EXCITATION} produces a voltage drop across the resistance R_{PAD} if the power supply connection being tested is not open circuit. The resistance R_{PAD} of the connection is low, of the order of 10 to 100 mOhms. If the connection 118, 120 between the bonding pad 114 under test and the external power bus 122 is properly established, the current circulates through the connection and the resistance R_{PAD} to generate a voltage of the order of 1 to 10 mV. However, if the connection 118, 120 under test is faulty, little or no current flows in the resistance and the voltage across it is smaller or zero.

The test module 200 comprises an input sensor formed by a pair of similar transistors 208 and 210 in current mirror configuration with sources connected to respective sides of the resistance R_{PAD}, drains connected through respective resistors 212 and 214 to the opposite polarity power bus 206 and gates connected together and to the drain of the transistor 208. The voltage across the resistor 214 during test is partly proportional to the voltage drop (if any) across the resistance R_{PAD}, which disturbs the balance of the current mirror. An auto-zero circuit 216 is included to correct for mismatch between the transistors 208 and 210. A programmable threshold circuit 218 defines a comparison level. A comparator amplifier 220 produces an output voltage which is proportional to the difference between a fixed voltage V_{COMP} and the sum of the signals from the resistor 214 of the input stage, from the auto-zero circuit 216 and from the threshold circuit 218. A flip-flop 222 stores a binary value representing the positive or negative output of the comparator amplifier 220. A built-in self test (‘BIST’) element is provided comprising a switch 224, a resistor 226 and a changeover switch 228 for connecting the source of the transistor 208 to the bond pad side of the resistance 116 instead of the side of the internal power bus 116 during the BIST operation. A similar test module (not shown) is provided for testing the opposite polarity power connections, with suitable adaptation.

The tests made using the test module 200 are sensitive to common mode noise on the internal power supply buses 102, 104 and 206 during test and are also sensitive to mismatch of components of the test module, producing DC offsets.

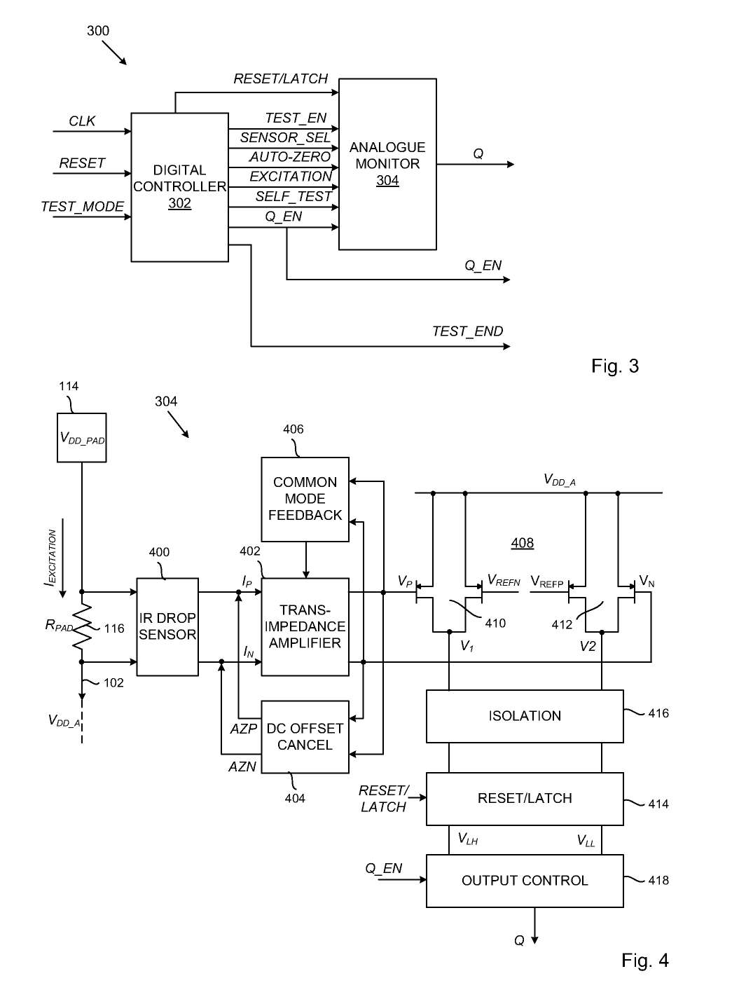

FIGS. 3 to 7 illustrate a test module 300 in a semiconductor device 301 in accordance with one embodiment of the invention, given by way of example, for testing the individual connections of the device 301. The semiconductor device 301 comprises an internal power bus such as 102, 104, parallel power connections such as 106 to 112 for connecting the internal power bus with the external power supply such as 122, and the test module 300. The test module 300 includes a sensor 400 for producing first and second differential sensor signals V_{P}, V_{N} which are functions of voltages V_{DD}_{_{—}}_{PAD}, V_{DD}_{_{—}}_{A} at spaced positions in a selected one of the parallel connections produced by current flowing therein. The test module 300 also includes first and second balanced differential pair comparator elements 410, 412 for receiving first and second reference signals V_{REFP}. V_{REFN} and for producing respectively a first comparator signal V₁ which is a function of the relative values of the first differential sensor signal V_{P} and the first reference signal V_{REFN}, and a second comparator signal V₂ which is a function of the relative values of the second differential sensor signal V_{N} and the second reference signal V_{Fp}. The test module 300 also includes an output element 414, 416, 418 for producing an output signal Q which is a function of the first and second comparator signals V₁, V₂.

In accordance with one embodiment of the invention, given by way of example, a method of testing parallel power connections for connecting an external power supply with an internal power bus in a semiconductor device 301 includes causing a current to flow through the parallel connections and producing first and second differential sensor signals V₂, V_{N} which are functions of voltages V_{DD}_{_{—}}_{PAD}, V_{DD}_{_{—}}_{A} at spaced positions in a selected one of the parallel connections produced by current flowing therein. The test method also includes applying first and second reference signals V_{REFP}, V_{REFN} as inputs to first and second balanced differential pair comparator elements 410, 412 and producing respectively a first comparator signal V₁ which is a function of the relative values of the first differential sensor signal V_{P} and the first reference signal V_{REFN}, and a second comparator signal V₂ which is a function of the relative values of the second differential sensor signal V_{N} and the second reference signal V_{REFP}. The test method also includes producing an output signal Q which is a function of the first and second comparator signals V₁, V₂.

In more detail, referring first to FIG. 3, the test module 300 comprises a digital controller 302 controlling the operation of an analog monitor 304. For the purposes of testing, the semiconductor device 301 assembled on the PCB may be installed in generic test equipment (not shown), which applies suitable inputs and electrical values to the device 301 and receives outputs from the test module 300. The inputs that the digital controller 302 receives from the test equipment include a clock signal CLK, and asynchronous signals RESET, causing the test module 300 to revert to its initial state, and TEST_MODE, triggering the test procedure of the test module 300. A signal LATCH synchronized with the clock signal CLK is also applied to the analog monitor 304 to cause it to latch its output Q for a period long enough for the test equipment to register the test result before the next connection test is selected. The output signal Q is asserted if the voltage across the resistance R_{PAD} of the connection under test is greater than a threshold value, signifying that the connection under test is defect free, and is de-asserted if the voltage across the resistance R_{PAD} of the connection under test is less than a threshold value, signifying that no current is flowing in the resistance R_{PAD} and that the connection under test is faulty.

The digital controller 302 produces a signal TEST_EN to enable start of the test procedure and a signal TEST_END after all the connections have been tested to inform the test equipment that the test procedure has terminated. A signal SENSOR_SEL connects the analog monitor 304 to test sequentially each of the connections 106 to 112. A signal AUTO-ZERO triggers a calibration phase in which the analog monitor 304 measures and cancels residual DC offset due to any mismatch of its components. A signal EXCITATION is a binary signal causing the analog monitor 304 to produce an excitation test current I_{EXCITATION} for the resistance R_{PAD} of the connection under test. A signal SELF_TEST triggers a BIST phase in which the analog monitor 304 performs a self-test routine. A signal Q_EN enables the test equipment to register the output Q of the analog monitor 304.

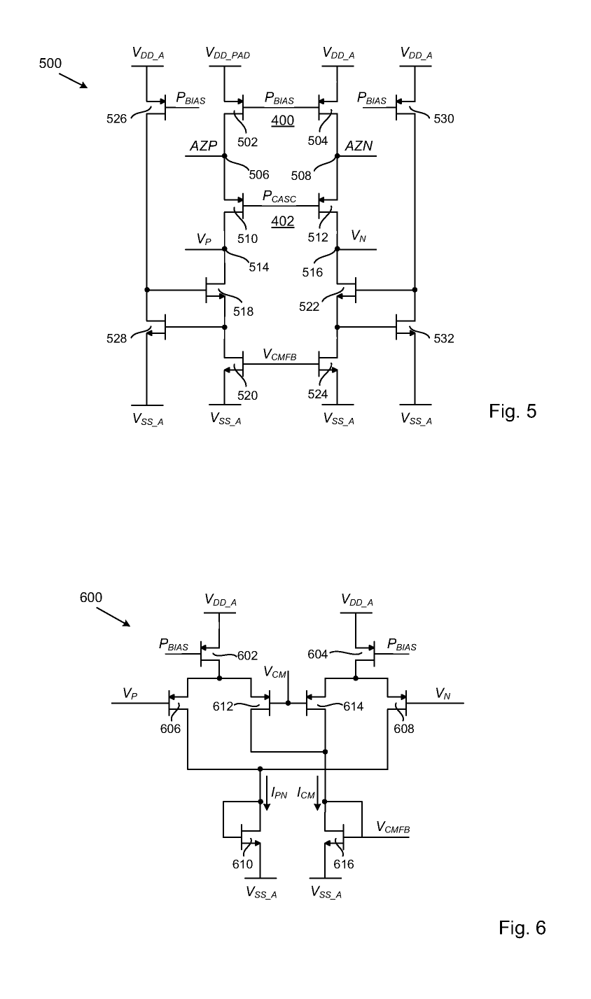

FIG. 4 shows an example of functional blocks of the analog monitor 304 and further detail of examples of their implementation are given in FIGS. 5, 6 and 7. It will be appreciated that FIGS. 4 to 7 may show separate functional blocks for the purposes of explanation but that such functional blocks may merge or be combined in practice. Elements of the analog monitor 304 are illustrated in FIG. 4 for the case of testing a connection for a positive voltage supply V_{DD}_{_{—}}_{A}. It will be appreciated that the analog monitor 304 typically also includes similar elements (not shown) for testing a connection for a negative voltage supply (or ground) V_{SS}_{_{—}}_{A}, whose circuits are inverted and whose components may be of opposite conductivity type compared to those illustrated in FIGS. 4 to 7.

The analog monitor 304 shown in FIG. 4 comprises a differential input sensor 400 and trans-impedance amplifier 402 for sensing the difference between the voltage V_{DD}_{_{—}}_{A} at the resistance R_{PAD} on the side of the internal power bus 102 and the voltage V_{DD}_{_{—}}_{PAD} at the resistance R_{PAD} on the side of the bond pad 114, due to the excitation test current I_{EXCITATION} for the resistance R_{PAD} of the connection under test. The differential input sensor 400 and trans-impedance amplifier 402 produce differential sensor signals V_{P}, V_{N} at their output. A DC offset element 404 is activated by the signal AUTO-ZERO to sense imbalance in the differential sensor signals V_{P}, V_{N} during a preliminary calibration phase, such as may be caused by mismatch of components of opposite conductivity type for example, and to store a correction which it applies to the differential input sensor 400 and trans-impedance amplifier 402 during the sensing phase. A common mode negative feedback element 406 applies a correction to the differential input sensor 400 and trans-impedance amplifier 402 as a function of variations of similar amplitude and direction in the combined values of the sensor signals V_{P}, V_{N}, caused by common mode noise for example.

The analog monitor 304 shown in FIG. 4 also comprises a differential comparator 408. The differential comparator 408 comprises first and second balanced differential pair comparator elements 410 and 412 for receiving first and second reference signals V_{REFN} and V_{REFP} as inputs. The first differential pair comparator element 410 produces a first comparator signal V₁ which is a function of the relative values of the first differential sensor signal V₂ and the first reference signal V_{REFN}. The second differential pair comparator element 412 produces a second comparator signal V₂ which is a function of the relative values of the second differential sensor signal V_{N} and the second reference signal V_{REFP}. The analog monitor 304 shown in FIG. 4 also comprises a positive feedback element 414 for latching the first and second comparator signals V₁ and V₂ and producing a binary output signal Q.

This example of the analog monitor 304 also includes an isolation element 416 for suppressing noise on the outputs of the balanced differential pair comparator elements 410 and 412. The positive feedback element 414 latches the first and second comparator signals V₁ and V₂ and produces corresponding first and second latch signals V_{LH} and V_{LL}, in response to the signal LATCH and is reset by the signal RESET. The binary output signal Q is transferred to the test equipment by an output control element 418 in response to the signal Q_EN.

FIGS. 5 to 7 illustrate an example of implementation of the analog circuits of FIG. 4 in more detail. FIG. 5 shows an example of implementation of a sensor 500 which comprises a differential cascode amplifier having a differential input stage as sensor 400 receiving the voltages V_{DD}_{_{—}}_{A} and V_{DD}_{_{—}}_{PAD} and a differential second stage as trans-impedance amplifier 402 for producing the first and second differential sensor signals. The cascode differential input stage 400 comprises a pair of p-type MOSFETs 502 and 504 connected differentially in common gate configuration. The source of the MOSFET 502 is connected to receive the voltage V_{DD}_{_{—}}_{PAD} and the source of the MOSFET 504 is connected to receive the voltage V_{DD}_{_{—}}_{A}. The gates of the MOSFETs 502 and 504 are connected together to receive a bias voltage P_{BIAS}. The drains of the MOSFETs 502 and 504 are connected respectively to nodes 506 and 508 which receive differential DC offset voltages AZP and AZN from the DC offset element 404. The cascode differential second stage 402 comprises a pair of p-type MOSFETs 510 and 512 connected differentially in common gate configuration with cascaded pairs of NMOS FETs 518, 520 and 522, 524 presenting a high impedance load. The source of the MOSFET 510 is connected to the node 506 and the source of the MOSFET 512 is connected to the node 508. The gates of the MOSFETs 510 and 512 are connected together to receive a bias voltage P_{CASC}. The drains of the MOSFETs 510 and 512 are connected respectively to nodes 514 and 516, at which the sensor signals appear as voltages V₂, V_{N}. The bias voltages P_{BIAS} and P_{CASC} are chosen so that the MOSFETs 502, 504, 510 and 512 are saturated and the differential DC offset voltages AZP and AZN are between the bias voltages P_{BIAS} and P_{CASC}.

The nodes 514 and 516 are connected to the negative (ground) voltage supply V_{SS}_{_{—}}_{A} through the respective pairs of n-type MOSFETs 518, 520 and 522, 524. The drain-source paths of the MOSFETs 518 and 520 are connected in series between the node 514 and the negative voltage supply V_{SS}_{_{—}}_{A}. A p-type MOSFET 526 and an n-type MOSFET 528 are connected in series between the positive voltage supply V_{DD}_{_{—}}_{A} and the negative voltage supply V_{SS}_{_{—}}_{A}. The gate of the MOSFET 526 receives the bias voltage P_{BIAS} and the MOSFET 526 acts as the load of the MOSFET 528. The MOSFETS 518, 520 and 528 are connected in a voltage gain boost configuration, with the gate of the MOSFET 528 connected to the source of the MOSFET 518 and to the drain of the MOSFET 520, and with the gate of the MOSFET 518 connected to the drains of the MOSFETs 526 and 528. The drain-source paths of the MOSFETs 522 and 524 are connected in series between the node 516 and the negative voltage supply V_{SS}_{_{—}}_{A}. A p-type MOSFET 530 and an n-type MOSFET 532 are connected in series between the positive voltage supply V_{DD}_{_{—}}_{A} and the negative voltage supply V_{SS}_{_{—}}_{A}. The gate of the MOSFET 530 receives the bias voltage P_{BIAS} and the MOSFET 530 acts as the load of the MOSFET. The MOSFETS 522, 524 and 532 are connected in a voltage gain boost configuration, with the gate of the MOSFET 532 connected to the source of the MOSFET 522 and to the drain of the MOSFET 524, and with the gate of the MOSFET 522 connected to the drains of the MOSFETs 530 and 532. The gates of the MOSFETs 520 and 524 are connected together to receive a voltage V_{CMFB} from the common mode negative feedback element 406 which adjusts the voltage at both of the nodes 514 and 516 by a corresponding amount to apply a correction to the sensor signals V₂, V_{N}, as a function of variations of similar amplitude and direction in the combined values of the voltages at the nodes 514 and 516. The two sides of the circuit 500 are symmetrical, to reduce or eliminate mismatch effects.

FIG. 6 shows a circuit 600 as an example of implementation of the common mode negative feedback element 406. The circuit 600 comprises a pair of p-type MOSFETs 602 and 604, whose sources are connected to the positive supply V_{DD}_{_{—}}_{A}. The gates of the MOSFETs 602 and 604 are connected together to receive the bias voltage P_{BIAS}. The drains of the MOSFETs 602 and 604 are connected to the sources of a pair of p-type MOSFETs 606 and 608, whose gates receive the sensor signals V₂, V_{N} respectively. The drains of the MOSFETs 606 and 608 are connected together and to the drain of a MOSFET 610, whose drain is connected to its gate and whose source is connected to the negative voltage supply V_{SS}_{_{—}}_{A}. The drains of the MOSFETs 602 and 604 are also connected to the sources of a pair of p-type MOSFETs 612 and 614, whose gates receive a reference voltage V_{CM}. The drains of the MOSFETs 612 and 614 are connected together and to the drain of a MOSFET 616, whose source is connected to the negative voltage supply V_{SS}_{_{—}}_{A}, and whose drain is connected to its gate and provides the voltage V_{CMFB}.

In operation, the reference voltage V_{CM} is set at a value equal to the nominal average value of the voltages V_{P} and V_{N}: (V_{P}+V_{N})/2, which is approximately equal to V_{DD}_{_{—}}_{A}/2. If the actual average value of the voltages V_{P} and V_{N} is equal to the reference voltage V_{CM}, the current I_{PN} flowing through the MOSFETs 606, 608 and 610 is equal to the current I_{CM} flowing through the MOSFETs 612, 614 and 616. The voltage V_{CMFB} at the drain and gate of the MOSFET 616 is then close to the nominal average value of the voltages V_{P} and V_{N}. If the average value of the voltages V_{P} and V_{N} is different from the reference voltage V_{CM}, the current I_{PN} flowing through the MOSFETs 606, 608 and 610 is different from the current I_{CM} flowing through the MOSFETs 612, 614 and 616. The voltage V_{CMFB} at the drain and gate of the MOSFET 616 is fed back to the MOSFETs 520 and 524 to tend to make the actual average value of the voltages V_{P} and V_{N} equal to their nominal average value V_{DD}_{_{—}}_{A}/2. The two sides of the circuit 600 are symmetrical, to reduce mismatch effects.

The DC offset cancelling circuit 404 may comprise an auxiliary amplifier which is activated by the signal AUTO-ZERO. In this example, the auxiliary amplifier samples the DC offset voltage difference between the nodes 514 and 516 during the calibration phase and stores the voltage difference on a capacitor. The DC offset cancelling circuit 404 applies the voltages AZP and AZN to the nodes 506 and 508 which modulate the currents in the MOSFETs 502, 510 and 504, 512 respectively. In this example, the DC offset cancelling circuit 404 has a common centroid device layout to reduce mismatch effects.

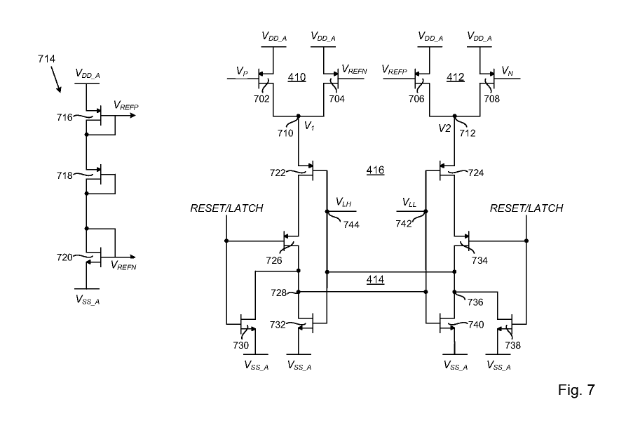

FIG. 7 shows an example of implementation of the differential comparator 408. The first and second balanced differential pair comparator elements 410 and 412 comprise pairs of p-type MOSFETs 702, 704 and 706, 708 respectively. The sources of the MOSFETs 702, 704 and 706, 708 are connected to the positive voltage supply V_{DD}_{_{—}}_{A}. The gates of the MOSFETs 702 and 708 are connected to the nodes 514 and 516 to receive the first differential sensor signal V₂ and the second differential sensor signal V_{N} respectively. The gates of the MOSFETs 704 and 706 are connected to receive the first and second reference signals V_{REFN} and V_{REFP} respectively. The drains of the MOSFETs 702, 704 are connected together and to a node 710. The drains of the MOSFETs 706, 708 are connected together and to a node 712. The first and second comparator signals V₁ and V₂ appear at the nodes 710 and 712 respectively.

The first and second reference signals V_{REFN} and V_{REFP} are generated by a reference generator 714. The reference generator 714 comprises p-type MOSFETs 716 and 718 and an n-type MOSFET 720, whose source-drain paths are connected in series between the positive voltage supply V_{DD}_{_{—}}_{A} and the negative voltage supply V_{SS}_{_{—}}_{A}. The source of the MOSFET 716 is connected to the positive voltage supply V_{DD}_{_{—}}_{A} and its drain is connected to its gate and to the source of the MOSFET 718. The drain of the MOSFET 718 is connected to its gate and to the drain and gate of the MOSFET 720. The source of the MOSFET 720 is connected to the negative voltage supply V_{SS}_{_{—}}_{A}. The first and second reference signals V_{REFN} and V_{REFP} are generated at the drain of the MOSFET 720 and at the drain of the MOSFET 716 respectively. The second reference signal V_{REFP} is approximately 1V higher than the first reference signal V_{REFN}. The voltages of the first and second differential sensor signals V₂ and V_{N} and of the first and second reference signals V_{REFN} and V_{REFP} are such that the MOSFETS 702, 704 and 706, 708 operate in the linear range, where the conductances of their drain-source paths are partly proportional to their gate-source voltages.

In this example, the isolation element 416 comprises a pair of p-type MOSFETs 722 and 724 whose sources are connected to the nodes 710 and 712 respectively. The drain of the MOSFET 722 is connected to the source of a p-type MOSFET 726 whose drain is connected to a node 728. The drains of n-type MOSFETs 730 and 732 are connected to the node 728 and their sources are connected to the negative voltage supply V_{SS}_{_{—}}_{A}. The drain of the MOSFET 724 is connected to the source of a p-type MOSFET 734 whose drain is connected to a node 736. The drains of n-type MOSFETs 738 and 740 are connected to the node 736 and their sources are connected to the negative voltage supply V_{SS}_{_{—}}_{A}. The node 728 is connected in positive feedback to the gates of the MOSFETs 724 and 740, which are connected together and to a node 742 at which the second latch signal V_{LL} appears. The node 736 is connected in positive feedback to the gates of the MOSFETs 722 and 732, which are connected together and to a node 744 at which the first latch signal V_{LH} appears. The gates of the MOSFETs 726 and 730 are connected together to receive the signal RESET. The gates of the MOSFETs 734 and 738 are connected together to receive the signal RESET.

In operation, in the absence of the excitation test current I_{EXCITATION}, due to absence of the signal EXCITATION or due to a defective connection for example, the sensor signals V_{P}, V_{N} are at equal voltages and the conductances of the MOSFETs 702 and 708 are equal. Since the reference voltage V_{RFEP} is higher than the reference voltage V_{REFN}, the conductance of the MOSFET 706 is less than the conductance of the MOSFET 704, the voltage of the second comparator signal V₂ is lower than the voltage of the first comparator signal V₁ and the latch voltage V_{LH} is lower than the latch voltage V_{LL}. When the excitation test current I_{EXCITATION} is flowing, the first sensor signal V₂ is at a higher voltage than the second sensor signal V_{N}. The conductance of the MOSFET 702 is sufficiently lower than the conductance of the MOSFET 708 for the first sensor signal V₂ to be at a lower voltage than the second sensor signal V_{N} and the latch voltage V_{LH} is higher than the latch voltage V_{LL}. The threshold of the voltage difference (V_{P}−V_{N}) at which the latch voltage difference (V_{LH}−V_{LL}) inverts is proportional to the difference (V_{REFP}−V_{REFN}) between the reference voltages.

When the signal RESET is de-asserted, at the voltage V_{SS}_{_{—}}_{A}, the MOSFETs 730 and 738 are turned OFF and the MOSFETs 726 and 734 are turned ON and, in the absence of the excitation test current I_{EXCITATION}, the latch 414 assumes the zero state in which the latch voltage V_{LH} is lower than the latch voltage V_{LL}.

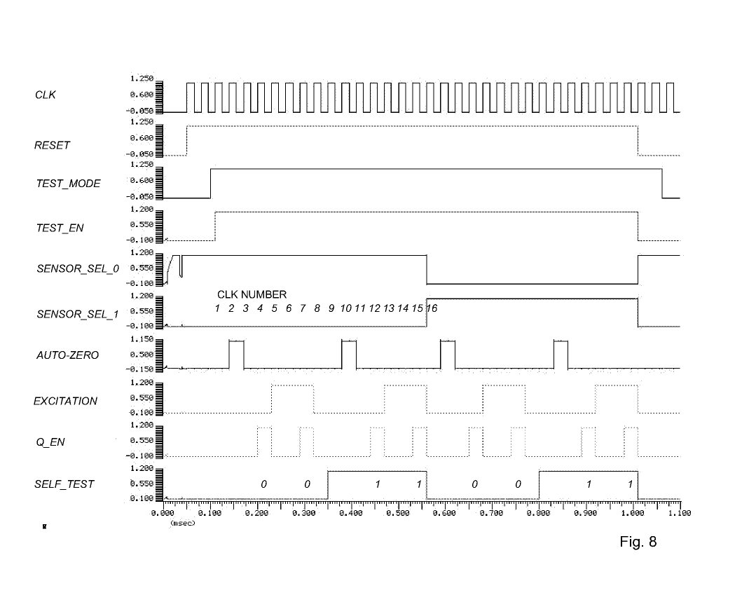

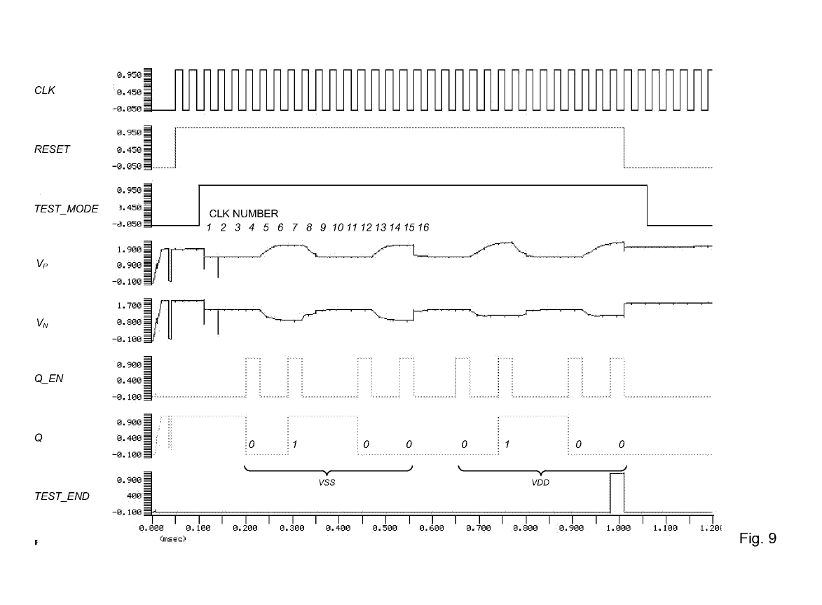

FIG. 8 shows an example of signals from the digital controller 302 and in the analog monitor 304 during an example of a test procedure using the test modules 500, 600 and 700. The test procedure comprises three parts: initialization, pad testing and test termination.

During initialization, all outputs signals of the digital controller 302, including the signals RESET and TEST_MODE, are de-asserted.

The pad testing starts when the signals RESET and TEST_MODE, are asserted. The outputs of the digital controller 302 are active and the clock signal CLK synchronizes operation of the analog monitor 304. The pad to be tested is selected by signals SENSOR_SEL_0 and SENSOR_SEL_1. The test for a single pad lasts sixteen cycles of the clock signal CLK starting from assertion of the signal TEST_EN. In clock cycle 1, the circuits run freely and the DC operating points of the analog monitor 304 are established. During clock cycle 2, the signal AUTO-ZERO is asserted and the DC offset element 404 sets and stores the voltages AZP and AZN to apply DC offset correction. The DC correction is checked during clock cycle 3. During clock cycle 4, the signal Q_EN is asserted and enables the test equipment to register the corresponding output Q of the analog monitor 304, which should be de-asserted. If the output Q is asserted during clock cycle 4, the test sequence will be invalid, because the DC offset correction is insufficient.

The signal EXCITATION is asserted during clock cycles 5, 6 and 7 to apply the voltages V_{DD}_{_{—}}_{PAD} and V_{DD}_{_{—}}_{A} to the pad under test. At clock cycle 7, when the sensor, amplifier and latch modules 408 have had time to settle, the signal Q_EN is asserted and enables the test equipment to register the corresponding output Q of the analog monitor 304, which is asserted if the excitation test current I_{EXCITATION} flows correctly in the pad connection under test and is de-asserted if the pad connection under test is defective.

After an inactive clock cycle 8, to allow the circuits to stabilize, the signal SELF_TEST is asserted during clock cycles 9 to 16 to trigger self-test of the analog monitor 304. The self-test routine is similar to clock cycles 1 to 8 but with the differential sensor signals V_{P}, V_{N} reversed. If the corresponding output Q of the analog monitor 304 is the opposite in clock cycle 15 from its value in clock cycle 7, the analog monitor 304 is not defective. If the corresponding output Q of the analog monitor 304 is the same in clock cycle 15 as its value in clock cycle 7, the analog monitor 304 is defective. The sequence of values of the output Q of the analog monitor 304 ‘0100’ signifies that the pad connection under test is not defective and the analog monitor 304 is not defective. The sequence of values of the output Q of the analog monitor 304 ‘0000’ signifies that the pad connection under test is defective and the analog monitor 304 is not defective. The signal RESET should always give the value ‘0’ for the output Q of the analog monitor.

Clock cycles 1 to 16 are repeated for all the pads to be tested, under the control of the signals SENSOR_SEL_0 and SENSOR_SEL_1. The signal TEST_END is asserted after all the pad connections have been tested to inform the test equipment that the test procedure has terminated.

The invention may be implemented partially in a computer program for running on a computer system, at least including code portions for performing steps of a method according to the invention when run on a programmable apparatus, such as a computer system or enabling a programmable apparatus to perform functions of a device or system according to the invention.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on computer readable storage medium or transmitted to the computer system via a computer readable transmission medium. All or some of the computer program may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; nonvolatile memory storage media including semiconductor-based memory units such as FLASH memory, EEPROM, EPROM, ROM; ferromagnetic digital memories; MRAM; volatile storage media including registers, buffers or caches, main memory, RAM, etc.; and data transmission media including computer networks, point-to-point telecommunication equipment, and carrier wave transmission media, just to name a few.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor substrate described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connections that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of testing parallel power connections of a semiconductor device, wherein the parallel power connections connect an internal power bus and an external power supply, the method comprising:
causing a current to flow through said parallel connections;
producing first and second differential sensor signals that are functions of voltages at spaced positions in a selected one of said parallel connections produced by said current flowing therein;
applying first and second reference signals as inputs to first and second balanced differential pair comparator elements, and producing respectively a first comparator signal that is a function of the relative values of said first differential sensor signal and said first reference signal, and a second comparator signal that is a function of the relative values of said second differential sensor signal and said second reference signal; and
producing an output signal that is a function of said first and second comparator signals.

2. The method of claim 1, wherein said first and second comparator signals are latched and said output signal has a binary value.

3. The method of claim 1, further comprising applying to said first and second differential sensor signals an offset feedback correction sensed during a calibration phase to correct imbalance between circuit elements producing said first and second differential sensor signals.

4. The method of claim 1, further comprising applying to said first and second differential sensor signals a common mode feedback correction that is a function of variation in combined values of said first and second differential sensor signals.

5. A semiconductor device having an internal power bus, parallel power connections for connecting said internal power bus with an external power supply, and a test module, wherein the test module comprises:
a sensor for producing first and second differential sensor signals which are functions of voltages at spaced positions in a selected one of said parallel connections produced by current flowing therein;
first and second balanced differential pair comparator elements for receiving first and second reference signals and for producing respectively a first comparator signal which is a function of the relative values of said first differential sensor signal and said first reference signal, and a second comparator signal which is a function of the relative values of said second differential sensor signal and said second reference signal; and
an output element for producing an output signal which is a function of said first and second comparator signals.

6. The semiconductor device of claim 5, wherein said output element comprises a positive feedback element for latching said first and second comparator signals and producing a binary value for said output signal.

7. The semiconductor device of claim 5, wherein said test module includes an offset correction element for applying to said sensor an offset correction sensed during a calibration phase to correct imbalance between circuit elements producing said first and second differential sensor signals.

8. The semiconductor device of claim 5, wherein said test module includes a common mode correction element for applying to said sensor a common mode feedback correction that is a function of variation in combined values of said first and second differential sensor signals.

9. The semiconductor device of claim 5, wherein said sensor comprises a cascode amplifier having an input stage receiving said voltages at spaced positions and a second stage for producing said first and second differential sensor signals.

10. A semiconductor device having an internal power bus, parallel power connections for connecting said internal power bus with an external power supply, and a test module, wherein the test module comprises:
a sensor for producing first and second differential sensor signals which are functions of voltages at spaced positions in a selected one of said parallel connections produced by current flowing therein;
first and second balanced differential pair comparator elements for receiving first and second reference signals and for producing respectively a first comparator signal which is a function of the relative values of said first differential sensor signal and said first reference signal, and a second comparator signal which is a function of the relative values of said second differential sensor signal and said second reference signal; and
an output element for producing an output signal that is a function of said first and second comparator signals, wherein said output element comprises a positive feedback element for latching said first and second comparator signals and producing a binary value for said output signal.

11. The semiconductor device of claim 10, wherein said test module includes an offset correction element for applying to said sensor an offset correction sensed during a calibration phase to correct imbalance between circuit elements producing said first and second differential sensor signals.

12. The semiconductor device of claim 10, wherein said test module includes a common mode correction element for applying to said sensor a common mode feedback correction that is a function of variation in combined values of said first and second differential sensor signals.

13. The semiconductor device of claim 10, wherein said sensor comprises a cascode amplifier having an input stage receiving said voltages at spaced positions and a second stage for producing said first and second differential sensor signals.
